(19) United States
(12) Patent Application Publication
(10) Pub. No.: US 2025/0393435 A1
(43) Pub. Date: Dec. 25, 2025

(54) DISPLAY DEVICE

(71) Applicant: Samsung Display Co., Ltd., Yongin-si (KR)

(72) Inventors: Kang Moon JO, Yongin-si (KR); Dong-Hyeon KI, Yongin-si (KR); Sun Kwang KIM, Yongin-si (KR); INYOUNG SON, Yongin-si (KR); Seong Young LEE, Yongin-si (KR)

(21) Appl. No.: 19/228,299

(22) Filed: Jun. 4, 2025

(30) Foreign Application Priority Data
Jun. 25, 2024 (KR) 10-2024-0083184
Jul. 2, 2024 (KR) 10-2024-0086846

(51) Int. Cl. H10K 59/38; H10K 59/122; H10K 59/131; H10K 59/35; H10K 59/80

(52) U.S. Cl. CPC H10K 59/38; H10K 59/122; H10K 59/131; H10K 59/352; H10K 59/353; H10K 59/873

(57) ABSTRACT

The present disclosure relates to a display device including a first substrate including light-emitting areas, and a non-light-emitting area surrounding the light-emitting area in plan view, transistors above the first substrate, light-emitting elements connected to the transistors, a common voltage wiring above the first substrate, and connected to the light-emitting elements through a contact opening in the non-light-emitting area, and a pixel definition layer that defines the light-emitting areas and the contact opening of a pixel group, the pixel group including a fifth light-emitting area and a second light-emitting area apart in a first direction with the contact opening therebetween, a sixth light-emitting area and a fourth light-emitting area apart from the fifth light-emitting area in a second direction crossing the first direction, and a third light-emitting area and a first light-emitting area apart from the second light-emitting area in the second direction.

### CROSS-REFERENCE TO RELATED APPLICATION

The present application claims priority to, and the benefit of, Korean Patent Application No. 10-2024-0086846, filed on Jul. 2, 2024, in the Korean Intellectual Property Office, and Korean Patent Application No. 10-2024-0083184, filed on Jun. 25, 2024, in the Korean Intellectual Property Office, the entire disclosures of which are incorporated herein by reference.

### BACKGROUND

### 1. Field

The present disclosure relates to a display device.

### 2. Description of the Related Art

A light-emitting diode is an element in which holes supplied from an anode and electrons supplied from a cathode are combined in an organic emission layer to form excitons, and light is emitted while the excitons are stabilized.

The light-emitting diode has several merits, such as a wide viewing angle, fast response speed, thin thickness, and low power consumption, such that the light-emitting diode is widely applied to various electrical and electronic devices, such as televisions, monitors, mobile phones, etc.

Recently, display devices including a color conversion layer have been proposed to implement high-efficiency display devices. The color conversion layer may convert incident light into a different color.

As usage increases, the light-emitting element degrades, which may change the characteristics of the light-emitting element. For example, as the luminous efficiency of the light-emitting element deteriorates over time, the luminescence characteristics thereof may deteriorate. Accordingly, various studies are being attempted to increase the luminous efficiency and the lifespan of light-emitting elements.

### SUMMARY

Embodiments provide a display device having improved lifespan of the plurality of light-emitting elements.

A display device according to one or more embodiments includes a first substrate including light-emitting areas, and a non-light-emitting area surrounding the light-emitting area in plan view, transistors above the first substrate, light-emitting elements connected to the transistors, a common voltage wiring above the first substrate, and connected to the light-emitting elements through a contact opening in the non-light-emitting area, and a pixel definition layer that defines the light-emitting areas and the contact opening of a pixel group, the pixel group including a fifth light-emitting area and a second light-emitting area apart in a first direction with the contact opening therebetween, a sixth light-emitting area and a fourth light-emitting area apart from the fifth light-emitting area in a second direction crossing the first direction, and a third light-emitting area and a first light-emitting area apart from the second light-emitting area in the second direction.

The fifth light-emitting area and the second light-emitting area may have a symmetrical shape centered on the contact opening.

The sixth light-emitting area and the third light-emitting area may have substantially a same planar shape, wherein the fourth light-emitting area and the first light-emitting area have substantially a same planar shape.

The area of the fifth light-emitting area and the area of the second light-emitting area may be substantially equal, wherein the area of the fifth light-emitting area is larger than the area of the sixth light-emitting area and the area of the fourth light-emitting area, and wherein the area of the second light-emitting area is larger than the area of the third light-emitting area and the area of the first light-emitting area.

The second light-emitting area, the contact opening, and the fifth light-emitting area may be arranged sequentially along the first direction, wherein the third light-emitting area, the first light-emitting area, the sixth light-emitting area, and the fourth light-emitting area, are arranged sequentially along the first direction.

The contact opening may be surrounded by the fifth light-emitting area, the second light-emitting area, the first light-emitting area, and the sixth light-emitting area.

Respective corners of the fifth light-emitting area and the second light-emitting area facing the contact opening may be chamfered along a side of the contact opening.

The pixel group may include a first pixel group, a second pixel group, and a third pixel group, wherein the first pixel group and the second pixel group are arranged along the first direction, wherein the first pixel group and the third pixel group are arranged along a third direction crossing the first direction and the second direction, and wherein the second pixel group and the third pixel group are arranged along a fourth direction crossing the third direction.

The first pixel group, the second pixel group, and the third pixel group may include the contact opening, wherein the contact opening in the first pixel group and the contact opening in the third pixel group are apart along the third direction, and wherein the contact opening in the second pixel group and the contact opening in the third pixel group are apart along the fourth direction.

The light-emitting elements may include a first electrode, a light-emitting layer, and a second electrode connected to the common voltage wiring through the contact opening, which are sequentially stacked.

The display device may further include an encapsulation layer above the light-emitting elements, a second substrate overlapping the first substrate, and including lighting areas respectively corresponding to the light-emitting areas, and a non-lighting area surrounding the lighting areas in plan view, a partition wall between the encapsulation layer and the second substrate, and defining partition wall openings that overlap the light-emitting areas, a color conversion layer and a transmitting layer within the partition wall openings, and color filters overlapping the lighting areas, wherein a planar shape of corresponding ones of the lighting areas is different from a planar shape of the light-emitting areas.

The corresponding ones of the lighting areas may be larger than the light-emitting areas.

The color filters may include a first color filter that overlaps the fifth light-emitting area and the second light-emitting area, a second color filter that overlaps the sixth light-emitting area and the third light-emitting area, and a third color filter that overlaps the fourth light-emitting area and the first light-emitting area.

The first color filter may be a green filter, wherein the second color filter is a red filter, and wherein the third color filter is a blue filter.

A display device according to one or more embodiments includes a first substrate including light-emitting areas, and a non-light-emitting area surrounding the light-emitting area in plan view, transistors above the first substrate, light-emitting elements connected to the transistors, an encapsulation layer above the light-emitting element, a pixel definition layer defining the light-emitting areas and a contact opening of a pixel group, a second substrate overlapping the first substrate, and including lighting areas corresponding to the light-emitting areas and a non-lighting area surrounding the lighting areas, color filters overlapping the lighting areas, a color conversion layer and a transmitting layer between the encapsulation layer and the color filters, and a common voltage wiring above the first substrate, connected to the light-emitting elements through the contact opening in the non-light-emitting area, wherein the pixel group includes a fifth light-emitting area and a second light-emitting area apart in a first direction with the contact opening in between, and having symmetry with respect to the contact opening, a sixth light-emitting area and a fourth light-emitting area apart from the fifth light-emitting area in a second direction crossing the first direction, and a third light-emitting area and a first light-emitting area apart from the second light-emitting area in the second direction, and wherein at least one of the lighting areas that overlap the first to sixth light-emitting areas has a shape that is different from that of the first to sixth light-emitting areas.

The lighting areas may include a fifth lighting area and a second lighting area overlapping the fifth light-emitting area and the second light-emitting area and having substantially a same shape, a sixth lighting area and a third lighting area overlapping the sixth light-emitting area and the third light-emitting area and having substantially a same shape, and a fourth lighting area and a first lighting area overlapping the fourth light-emitting area and the first light-emitting area and having substantially a same shape.

The first to sixth lighting areas may be larger than corresponding ones of the first to sixth light-emitting areas, wherein the first to sixth lighting areas have a different shape from the corresponding ones of the first to sixth light-emitting areas.

The color filters may include a first color filter overlapping the fifth lighting area and the second lighting area, a second color filter overlapping the third lighting area and the sixth lighting area, and a third color filter overlapping the first lighting area and the fourth lighting area, wherein the first color filter, the second color filter, and the third color filter correspond to different respective colors.

The first to sixth lighting areas may have a quadrangular shape.

The fifth lighting area and the second lighting area might not overlap the contact opening.

An electronic device according to one or more embodiments includes a display device including a first substrate including light-emitting areas, and a non-light-emitting area surrounding the light-emitting area in plan view, transistors above the first substrate, light-emitting elements connected to the transistors, a common voltage wiring above the first substrate, and connected to the light-emitting elements through a contact opening in the non-light-emitting area, and a pixel definition layer that defines the light-emitting areas and the contact opening of a pixel group, the pixel group including a fifth light-emitting area and a second light-emitting area apart in a first direction with the contact opening therebetween, a sixth light-emitting area and a fourth light-emitting area apart from the fifth light-emitting area in a second direction crossing the first direction, and a third light-emitting area and a first light-emitting area apart from the second light-emitting area in the second direction.

The electronic device may include a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, a head-mounted display (HMD), a virtual reality (VR) device, or an augmented reality (AR) device.

According to embodiments, the display device having improved luminescence characteristics may be provided by improving the luminous efficiency and lifespan of the plurality of light-emitting elements.

### BRIEF DESCRIPTION OF THE DRAWINGS

FIG. 1 is a schematic exploded perspective view of a display device according to one or more embodiments.

FIG. 2 is a schematic cross-sectional view of a display panel according to one or more embodiments.

FIG. 3 is a circuit diagram of one pixel of a display device according to one or more embodiments.

FIG. 4 is a top plan view of a display device according to one or more embodiments.

FIG. 5 is a top plan view illustrating a light-emitting area of a display device according to one or more embodiments.

FIG. 6 is an enlarged view of a part of FIG. 5.

FIG. 7 is a plan view showing a light-emitting area of a display device according to one or more embodiments.

FIG. 8 is a cross-sectional view taken along the line I-I′ of FIG. 4.

FIG. 9 is a cross-sectional view taken along the line II-II′ of FIG. 4.

FIG. 10 to FIG. 13 are plan views illustrating a part of a display device according to some embodiments.

FIG. 14 is a block diagram of an electronic device according to one or more embodiments.

FIG. 15 shows schematic diagrams of electronic devices according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are

ed to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group including X, Y, and Z,” and “at least one selected from the group including X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

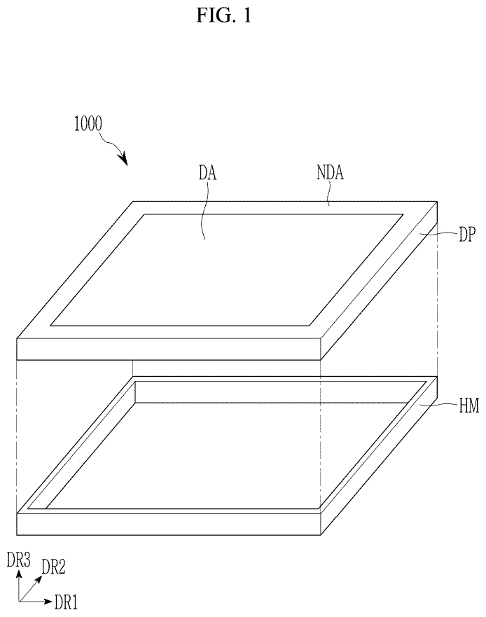

Hereinafter, a display device according to one or more embodiments is described with reference to FIG. 1 to FIG. 9.

First, a display device 1000 according to one or more embodiments is described as follows with reference to FIG. 1 to FIG. 3.

FIG. 1 is a schematic exploded perspective view of a display device according to one or more embodiments.

Referring to FIG. 1, a display device 1000 according to one or more embodiments may include a display panel DP and a housing HM.

In the display panel DP, one surface on which an image is displayed may be parallel to a plane defined by a first direction DR1 and by a second direction DR2. The normal direction of one surface on which the image is displayed (e.g., the thickness direction of the display panel DP) is indicated by a third direction DR3. A front (or an upper surface) and a back (or a lower surface) of each member may be distinguished by the third direction DR3. However, the directions indicated by the first to third directions DR1, DR2, and DR3 are relative concepts and may be changed to other directions.

The display panel DP may be a flat rigid display panel, but it is not limited thereto, and the display panel DP may be a flexible display panel. The display panel DP may be an organic light-emitting panel. However, the type of the display panel DP is not limited to this and may be changed to various types of panels. For example, the display panel DP may be a liquid crystal panel, an electrophoresis display panel, an electrowetting display panel, etc.

Additionally, the display panel DP may be a next generation display panel, such as a micro light-emitting diode display panel, a quantum dot light-emitting diode display panel, and a quantum dot organic light-emitting diode display panel.

A micro-light-emitting diode (Micro-LED) display panel may have each pixel including a light-emitting diode with a size of 10 to 100 micrometers. These micro-light-emitting diode display panels may have advantages of using inorganic materials, omitting a backlight, having fast reaction speed, realizing high luminance with low electric power, and not being broken when bending.

The quantum dot light-emitting diode display panel may be made by attaching a film including quantum dots or by being formed of a material including quantum dots. The quantum dots are made of inorganic materials, such as indium, cadmium, etc., which they emit light by themselves, and are particles with a diameter of several nanometers or less. By adjusting the particle size of the quantum dots, it is possible to display light of a desired color. The quantum dot-organic light-emitting diode (QD-OLED) display panel is made by a method using a blue organic light-emitting diode as a light source, and attaching a film including red and green quantum dots thereon or depositing a material including red and green quantum dots to implement a color. The display device 1000 according to one or more embodiments may be formed of various display panels.

As shown in FIG. 1, the display panel DP may include a display area DA on which the image is displayed, and a non-display area NDA adjacent to the display area DA. The non-display area NDA may be an area where the image is not displayed. The display area DA may have, for example, a square shape, and the non-display area NDA may have a shape that surrounds the display area DA. However, the present disclosure is not limited to this, and the shape of the display area DA and the non-display area NDA may be changed in various ways depending on a relative design.

The housing HM may provide an internal space (e.g., predetermined internal space). The display panel DP may be mounted inside the housing HM. In addition to the display panel DP, various electronic components (e.g., a power supply unit, a storage device, and a sound input and/or output module) may be mounted inside the housing HM.

The display device 1000 according to one or more embodiments is a device that displays a moving image and/or a still image. The display device 1000 may be applied to portable electronic devices such as mobile phones, smartphones, tablet personal computers (PCs), mobile communication terminals, electronic notebooks, electronic books, portable multimedia players (PMPs), navigations, and ultra-mobile PCs (UMPCs). For example, the display device 1000 may be applied to a display unit of a television, a laptop computer, a monitor, a billboard, or the Internet of Things (IoT). Alternatively, in one or more embodiments, the display device 1000 may be applied to a smartwatch, a watch phone, a virtual reality (VR) device, an augmented reality (AR) device, and/or a head-mounted display device (HMD) (e.g., for implementing virtual reality and/or augmented reality).

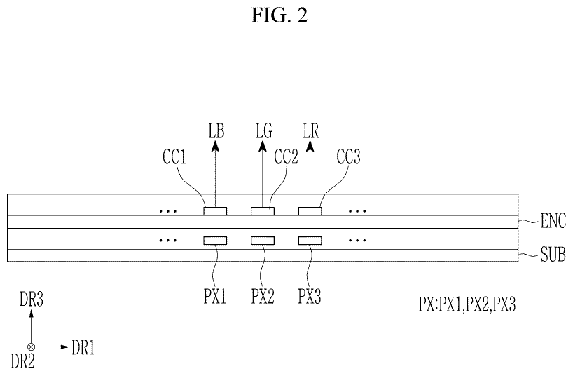

FIG. 2 is a schematic cross-sectional view of a display panel according to one or more embodiments.

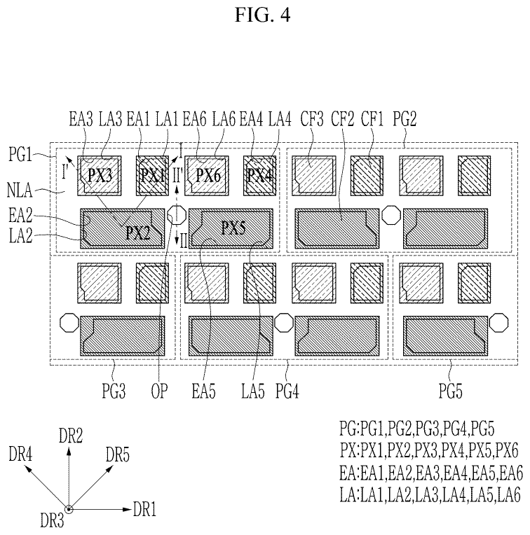

Referring to FIG. 2, a plurality of pixels PX may be positioned on a substrate SUB corresponding to the display area DA of FIG. 1. A plurality of pixels PX may include a first pixel PX1, a second pixel PX2, and a third pixel PX3. Each pixel PX may include a plurality of transistors and a light-emitting element connected thereto. In this specification, the shape and arrangement of the plurality of pixels PX may be changed in various ways. The detailed description therefor is described with reference to FIG. 4 to FIG. 6.

An encapsulation layer ENC may be positioned on the plurality of pixels PX. The display area DA may be protected from external air or moisture through the encapsulation layer ENC. The encapsulation layer ENC may be provided integrally to overlap the entire surface of the display area DA, and a part thereof may also be positioned over the non-display area NDA.

On the encapsulation layer ENC, a transmission part CC1, a first color converter CC2, and a second color converter CC3 may be positioned. The transmission part CC1 may overlap the first pixel PX1, the first color converter CC2 may overlap the second pixel PX2, and the second color converter CC3 may overlap the third pixel PX3.

The light emitted from the first pixel PX1 may pass through the transmission part CC1 to provide a blue light LB. The light emitted from the second pixel PX2 may pass through the first color converter CC2 to provide a green light LG. The light emitted from the third pixel PX3 may pass through the second color converter CC3 to provide a red light RB.

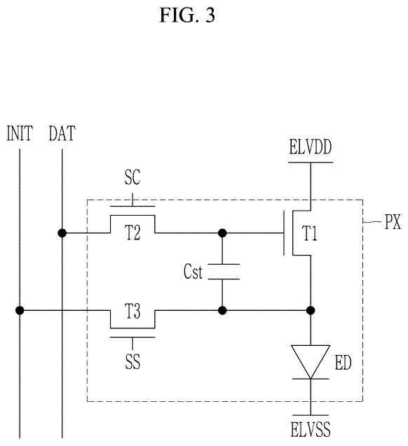

FIG. 3 is a circuit diagram of one pixel of a display device according to one or more embodiments.

Each of a plurality of pixels PX according to one or more embodiments, as shown in FIG. 3, may include a plurality of transistors T1, T2, and T3, a capacitor Cst, and at least one light-emitting diode ED that is a light-emitting element. In one or more embodiments, an example in which one pixel PX includes one light-emitting element ED is described as a reference.

The plurality of transistors T1, T2, and T3 includes a driving transistor T1, a switching transistor T2, and an initialization transistor T3. The first electrode and the second electrode, which will be described below, are for distinguishing two electrodes positioned on both sides of the channels of each transistor T1, T2, and T3, and may be a source electrode or a drain electrode.

A gate electrode of the driving transistor T1 is connected to one terminal of the capacitor Cst, a first electrode of the driving transistor T1 is connected to a driving voltage line for transmitting a driving voltage ELVDD, and a second electrode of the driving transistor T1 is connected to an anode of the light-emitting diode ED and the other terminal of the capacitor Cst. The driving transistor T1 may receive a data voltage DAT depending on a switching operation of the switching transistor T2 to supply a driving current to the light-emitting diode ED depending on the voltage stored in the capacitor Cst.

A gate electrode of the switching transistor T2 is connected to a first scan line for transmitting a first scan signal SC, a first electrode of the switching transistor T2 is connected to a data line capable of transmitting a data voltage DAT or a reference voltage, and a second electrode of the switching transistor T2 is connected to one terminal of the capacitor Cst and the gate electrode of the driving transistor T1. The switching transistor T2 is turned on depending on the first scan signal SC, thereby transmitting the reference voltage or the data voltage DAT to the gate electrode of the driving transistor T1 and one terminal of the capacitor Cst.

A gate electrode of the initialization transistor T3 is connected to a second scan line for transmitting a second scan signal SS, a first electrode of the initialization transistor T3 is connected to the other terminal of the capacitor Cst, the second electrode of the driving transistor T1, and the anode of the light-emitting diode ED, and a second electrode of the initialization transistor T3 is connected to an initialization voltage line for transmitting an initialization voltage INIT. The initialization transistor T3 is turned on depending on the second scan signal SS to transmit the initialization voltage INIT to the anode of the light-emitting diode ED and the other terminal of the capacitor Cst, thereby initializing the voltage of the anode of the light-emitting diode ED.

One terminal of the capacitor Cst is connected to the gate electrode of the driving transistor T1, and the other terminal is connected to the first electrode of the initialization transistor T3 and the anode of the light-emitting diode ED. The cathode of the light-emitting diode ED is connected to a common voltage line for transmitting a common voltage ELVSS.

The light-emitting diode ED may emit light of luminance according to the driving current generated by the driving transistor T1.

As an example of the operation of the circuit diagram shown in FIG. 3, one example of the operation during one frame will be described. Here, a case that the transistors T1, T2, and T3 are n-type channel transistors is described as an example, but is not limited thereto.

When one frame starts, the first scan signal SC of a high level and the second scan signal SS of a high level are supplied in the initialization period, so that the switching transistor T2 and the initialization transistor T3 are turned on. Through the turned-on switching transistor T2, the reference voltage from the data line is supplied to the gate electrode of the driving transistor T1 and to one terminal of the capacitor Cst, and the initialization voltage INIT is supplied to the second electrode of the driving transistor T1, to another terminal of the capacitor Cst, and to the anode of the light-emitting diode ED through the turned-on initialization transistor T3. Accordingly, during the initialization period, the anode of the light-emitting diode ED and the second electrode of the driving transistor T1 are initialized to the initialization voltage INIT. At this time, the voltage difference between the reference voltage and the initialization voltage INIT is stored in the capacitor Cst.

Next, when the second scan signal SS reaches a low level in a state in which the first scan signal SC of high level is maintained in a sensing period, the switching transistor T2 remains in the turned-on state and the initialization transistor T3 is turned off. The gate electrode of the driving transistor T1 and one terminal of the capacitor Cst maintain the reference voltage through the turned-on switching transistor T2, and the second electrode of the driving transistor T1 and the anode of the light-emitting diode ED are disconnected from the initialization voltage INIT through the turned-off initialization transistor T3. Accordingly, if the current flows from the first electrode to the second electrode and the voltage of the second electrode becomes “reference voltage-Vth,” the driving transistor T1 is turned off. Vth represents a threshold voltage of the driving transistor T1. At this time, the voltage difference between the gate electrode and the second electrode of the driving transistor T1 is stored in the capacitor Cst, and the sensing of the threshold voltage Vth of the driving transistor T1 is completed. By generating the compensated data signal reflecting the characteristic information sensed during the sensing period, the characteristic deviation of the driving transistor T1, which may be different for each pixel, may be externally compensated.

Next, in a data input period, when the first scan signal SC of a high level is supplied and the second scan signal SS of a low level is supplied, the switching transistor T2 is turned on, and the initialization transistor T3 is turned off. Through the turned-on switching transistor T2, the data voltage DAT from the data line is supplied to the gate electrode of the driving transistor T1 and to one terminal of the capacitor Cst. At this time, the second electrode of the driving transistor T1 and the anode of the light-emitting diode ED may substantially maintain the potential in the sensing period due to the driving transistor T1 in the turned-off state.

Next, the driving transistor T1, which is turned on by the data voltage DAT transferred to the gate electrode during the light emission period, generates the driving current according to the data voltage DAT, and the light-emitting diode ED may emit light by the driving current.

Hereinafter, a detailed structure of the display device according to one or more embodiments is described with reference to FIG. 4 to FIG. 9.

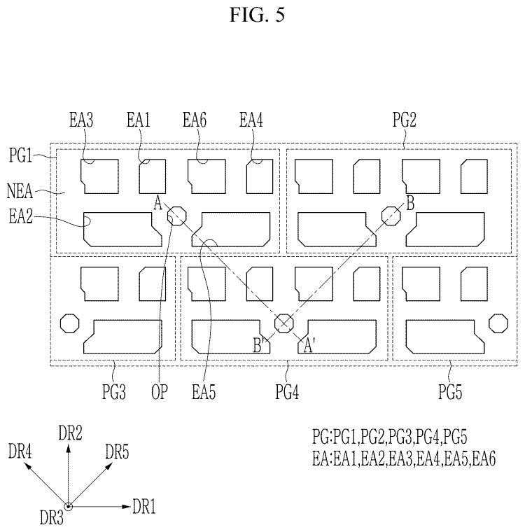

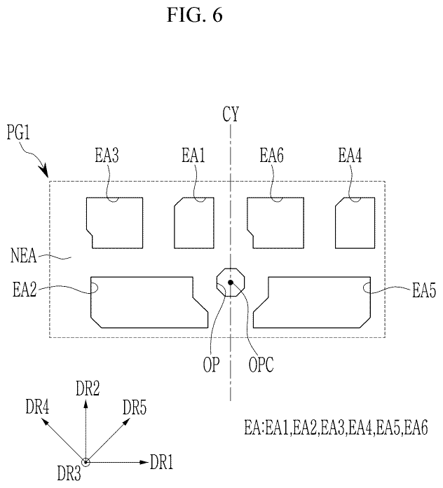

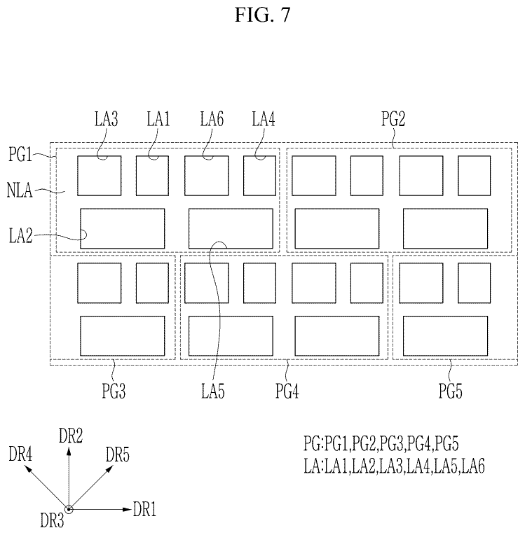

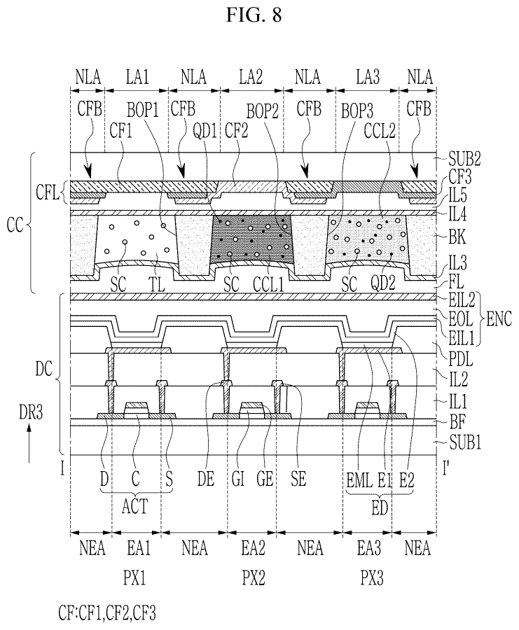

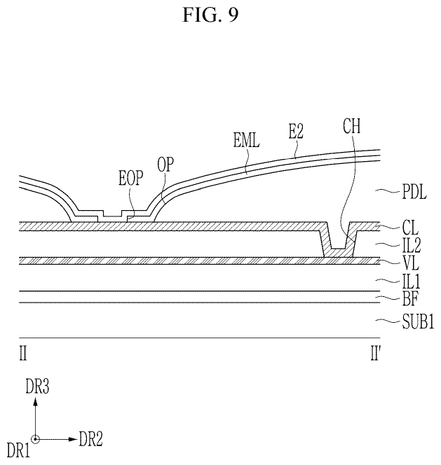

FIG. 4 is a plan view of a display device according to one or more embodiments. FIG. 5 is a plan view illustrating a light-emitting area of a display device according to one or more embodiments. FIG. 6 is an enlarged view of a part of FIG. 5. FIG. 7 is a plan view showing a light-emitting area of a display device according to one or more embodiments. FIG. 8 is a cross-sectional view taken along the line I-I′ of FIG. 4. FIG. 9 is a cross-sectional view taken along the line II-II′ of FIG. 4. For example, FIG. 4 to FIG. 6 are plan views illustrating a part of a display area DA of a display device 1000 according to one or more embodiments.

First, referring to FIG. 4 to FIG. 7 along with FIG. 1 to FIG. 3, a planar arrangement of the plurality of light-emitting areas EA and the lighting area LA included in each plurality of pixels PX is described.

The display device 1000 according to one or more embodiments may include a plurality of pixel groups PG including a plurality of pixels PX and at least one contact opening OP. For example, one pixel group PG may include one contact opening OP, a first pixel PX1, a second pixel PX2, and a third pixel PX3 displaying different respective colors, and a fourth pixel PX4, a fifth pixel PX5, and a sixth pixel PX6 displaying different respective colors.

Within one pixel group PG, the first pixel PX1, the second pixel PX2, and the third pixel PX3 may form one sub-group, and the fourth pixel PX4, the fifth pixel PX5, and the sixth pixel PX6 may form another sub-group.

The first pixel PX1 and the fourth pixel PX4 may display the first color, the second pixel PX2 and the fifth pixel PX5 may display the second color, and the third pixel PX3 and the sixth pixel PX6 may display the third color. Here, the first color may be blue, the second color may be green, and the third color may be red. However, this is an example only, and the first color, second color, and third color may be changed in various ways.

Referring to FIGS. 3 and 9, a wiring to which the above-described common voltage ELVSS is applied and the light-emitting element ED may be connected through a contact opening OP defined by the pixel definition layer PDL in a non-light-emitting area NEA. That is, the common voltage wiring VL to which the common voltage ELVSS is applied and the second electrode E2 of the light-emitting element ED may be electrically connected to each other within the contact opening OP. The detailed description thereof is described further with reference to FIG. 9 later.

One pixel group PG may include a plurality of light-emitting areas EA corresponding to each of a plurality of pixels PX and a plurality of non-light-emitting areas NEA surrounding them. The non-light-emitting area NEA may be positioned between the plurality of light-emitting areas EA. That is, the plurality of light-emitting areas EA may be surrounded by the non-light-emitting areas NEA.

The light-emitting area EA and the non-light-emitting area NEA may be defined by a pixel definition layer PDL positioned on the first substrate SUB1. That is, the light-emitting area EA may mean the pixel opening of the pixel definition layer PDL where the light-emitting layer is positioned, and the non-light-emitting area NEA may mean the area where the pixel definition layer PDL is positioned.

In one or more embodiments, one pixel group PG may include a first light-emitting area EA1, a second light-emitting area EA2, a third light-emitting area EA3, a fourth light-emitting area EA4, a fifth light-emitting area EA5, and a sixth light-emitting area EA6 corresponding to the first to sixth pixels PX1, PX2, PX3, PX4, PX5, and PX6, respectively.

The contact opening OP positioned within one pixel group PG may be positioned approximately at the center of the pixel group PG. For the contact opening OP as a reference, the first light-emitting area EA1, the second light-emitting area EA2, and the third light-emitting area EA3 may be positioned on one side of the first direction DR1, and the fourth light-emitting area EA4, the fifth light-emitting area EA5, and the sixth light-emitting area EA6 may be positioned on the other side of the first direction DR1.

The third light-emitting area EA3, the first light-emitting area EA1, the sixth light-emitting area EA6, and the fourth light-emitting area EA4 may be arranged sequentially along the first direction DR1 to form a first row, and the second light-emitting area EA2, the contact opening OP, and the fifth light-emitting area EA5 may be arranged sequentially along the first direction DR1 to form a second row. That is, the contact opening OP may be positioned in a different row from the first light-emitting area EA1, the third light-emitting area EA3, the fourth light-emitting area EA4, and the sixth light-emitting area EA6.

The contact opening OP within one pixel group PG may be surrounded by the plurality of light-emitting areas EA. For example, the contact opening OP may be entirely surrounded (e.g., in plan view) by the first light-emitting area EA1, the second light-emitting area EA2, the fifth light-emitting area EA5, and the sixth light-emitting area EA6.

Among the first to sixth light-emitting areas EA1, EA2, EA3, EA4, EA5, and EA6 included in one pixel group PG, the first light-emitting area EA1, the second light-emitting area EA2, and the third light-emitting area EA3, which are positioned on one side of the first direction DR1 with the contact opening OP at the center, have different shapes and areas on a plane, and the fourth light-emitting area EA4, the fifth light-emitting area EA5, and the sixth light-emitting area EA6 positioned on the other side of the first direction DR1 may have different shapes and areas in a plane.

For example, as shown in FIG. 6, the area of the second light-emitting area EA2 may be larger than the areas of the first light-emitting area EA1 and the third light-emitting area EA3 included in the first pixel group PG1, and the area of the third light-emitting area EA3 may be larger than the area of the first light-emitting area EA1. That is, the area of the second light-emitting area EA2 may be the largest, and the area of the first light-emitting area EA1 may be the smallest.

Additionally, the area of the fifth light-emitting area EA5 may be larger than the areas of the fourth light-emitting area EA4 and the sixth light-emitting area EA6 included in the first pixel group PG1, and the area of the sixth light-emitting area EA6 may be larger than the area of the fourth light-emitting area EA4. That is, the area of the fifth light-emitting area EA5 may be the largest, and the area of the fourth light-emitting area EA4 may be the smallest.

Some of the first to sixth light-emitting areas EA1, EA2, EA3, EA4, EA5, and EA6 included in one pixel group PG may have substantially the same area and shape in a plane, and some of the others may have substantially the same area and may have a symmetrical planar shape.

For example, as shown in FIG. 6, the first light-emitting area EA1 included in the first pixel group PG1 may have the same area as the fourth light-emitting area EA4 on a plane, and have a polygonal shape with the same chamfered corners. The third light-emitting area EA3 may have the same area as the sixth light-emitting area EA6 on a plane, and have a polygon shape with substantially the same chamfered corners.

In addition, the second light-emitting area EA2 may have substantially the same area as the fifth light-emitting area EA5, and may have a shape symmetrical to each other on a plane with an arbitrary symmetry line CY passing through the center OPC of the contact opening OP, and extending along the second direction DR2 as a reference.

Among the corners of each of the second light-emitting area EA2 and the fifth light-emitting area EA5, the corner facing the contact opening OP may be chamfered along the side of the contact opening OP. That is, among the corners of the second light-emitting area EA2 and the fifth light-emitting area EA5, the chamfered corners may have substantially the same planar shape as the side surface of the contact opening OP. However, the planar shape of each of the first to sixth light-emitting areas EA1, EA2, EA3, EA4, EA5, and EA6 is not limited to this, and may be changed in various ways. For example, each of the first to sixth light-emitting areas EA1, EA2, EA3, EA4, EA5, and EA6 may have a rhombus or a rhombus-like octagonal shape, but is not limited thereto and may have any shape, such as a quadrangle or a polygon.

In one or more embodiments, the second light-emitting area EA2 and the fifth light-emitting area EA5 are depicted as having a mirror-symmetric shape with the arbitrary symmetry line CY passing through the center of the contact opening OP as a reference. However, the symmetry relationship between the second light-emitting area EA2 and the fifth light-emitting area EA5 is not limited thereto, and may be changed in various ways.

In some embodiments, the second light-emitting area EA2 and the fifth light-emitting area EA5 may have rotationally symmetrical shapes. That is, the second light-emitting area EA2 may have substantially the same shape when symmetrically rotated 180° in the direction parallel to the direction (e.g., the third direction DR3) vertical to the fifth light-emitting area EA5 as the rotation axis. However, this is an example, and the number of the contact opening OP and pixels PX included in one pixel group PG, and the planar area, shape, and arrangement relationship of the plurality of light-emitting areas EA corresponding to each of the plurality of pixels PX may be changed in various ways.

In FIG. 6, the first pixel group PG1 is described as a reference, but because the description thereof may be applied substantially the same way to each of the second to fifth pixel groups PG2, PG3, PG4, and PG5, the detailed description thereof is omitted.

In one or more embodiments, the plurality of pixel groups PG may be arranged along the first direction DR1 to form a plurality of rows. For example, the first pixel group PG1 and the second pixel group PG2 may be arranged along the first direction DR1 to form the first row, and the third pixel group PG3, the fourth pixel group PG4, and the fifth pixel group PG5 may be arranged along the first direction DR1 to form the second row (e.g., see FIG. 5).

Among the plurality of pixel groups PG positioned in the different rows, one pixel group PG and another pixel group PG may be arranged along the third direction DR5, which is a diagonal direction intersecting the first direction DR1 and the second direction DR2, and one pixel group PG and another pixel group PG positioned in the different rows may be arranged along the fourth direction DR4, which is a diagonal direction intersecting the first direction DR1, the second direction DR2, and the third direction DR5. For example, the fourth pixel group PG4 positioned in the second row may be arranged along the third direction DR5, which is a diagonal direction, to the second pixel group PG2 positioned in the first row, and may be arranged along the fourth direction DR4, which is a diagonal direction, to the first pixel group PG1 positioned in the first row.

Accordingly, among the light-emitting areas EA included in the fourth pixel group PG4, the first to third light-emitting areas EA1, EA2, and EA3 overlap, or are aligned with, the fourth to sixth light-emitting areas EA4, EA5, and EA6 included in the first pixel group PG1 in the second direction DR2, and among the light-emitting areas EA included in the fourth pixel group PG4, the fourth to sixth light-emitting areas EA4, EA5, and EA6 may overlap, or may be aligned with, the first to third light-emitting areas EA1, EA2, and EA3 included in the second pixel group PG2 in the second direction DR2.

Among the plurality of pixel groups PG positioned in the same row, some of the light-emitting areas EA included in one pixel group PG may have a shape that is symmetrical on a plane with some of the light-emitting area EA included in another pixel group PG. For example, the fifth light-emitting area EA5 included in the first pixel group PG1 may have a symmetrical shape to the second light-emitting area EA2 included in the second pixel group PG2. Here, “symmetric” may mean a mirror-symmetric shape, such as the symmetric relationship between the second light-emitting area EA2 and the fifth light-emitting area EA5 included in one pixel group PG.

In FIG. 4 and FIG. 5, the second light-emitting area EA2 and the fifth light-emitting area EA5, which are positioned on respective pixel groups PG positioned in the different rows, and that overlap, or are aligned, in the second direction DR2 on a plane, are depicted as having an asymmetrical planar shape, but the present disclosure is not limited thereto and may be variously modified. In one or more embodiments, and for example, the second light-emitting area EA2 and the fifth light-emitting area EA5 included in the third pixel group PG3 have a mirror-symmetric shape with the symmetry line extending along the second direction DR2 and passing through the contact opening OP as the center, and may have a symmetrical shape with the second light-emitting area EA2 included in the third pixel group PG3 and the fifth light-emitting area EA5 included in the first pixel group PG1.

That is, the second light-emitting area EA2 included in the fourth pixel group PG4 and the fifth light-emitting area EA5 included in the first pixel group PG1 may have a mirror-symmetric shape with the symmetry line extending along the first direction DR1 and passing through the centers of the first light-emitting area EA1 and the third light-emitting area EA3 included in the fourth pixel group PG4 as a reference.

Additionally, the fifth light-emitting area EA5 included in the fourth pixel group PG4 and the second light-emitting area EA2 included in the second pixel group PG2 may have a symmetrical shape. That is, the fifth light-emitting area EA5 included in the fourth pixel group PG4 and the second light-emitting area EA2 included in the second pixel group PG2 may have a mirror-symmetric shape with a symmetry line extending along the first direction DR1 and passing through the center of the fourth light-emitting area EA4 and the sixth light-emitting area EA6 included in the fourth pixel group PG4.

In one or more embodiments, among the pixel groups PG positioned in the same row, the contact opening OP included in one pixel group PG and the contact opening OP included in another pixel group PG may be positioned apart from each other along the first direction DR1, among pixel groups PG positioned in the different adjacent rows, the contact opening OP included in one pixel group PG and the contact opening OP included in another pixel group PG may be positioned apart from each other along the third direction DR5, which is a diagonal direction. In addition, among the pixel groups PG positioned in the different adjacent rows, the contact opening OP included in one pixel group PG and the contact opening OP included in another pixel group PG may be positioned apart from each other along the fourth direction DR4, which is a diagonal direction.

That is, the contact openings OP included in each of the pixel groups PG positioned in one row and the contact openings OP included in each of the pixel groups PG positioned in another row may be arranged in a zigzag shape on one side and the other side with respect to the second direction DR2 and along the first direction DR1 with respective light-emitting areas EA therebetween.

For example, the contact openings OP included in each of the first pixel group PG1 and the second pixel group PG2 positioned in the first row may be positioned apart along the first direction DR1.

The contact opening OP included in the first pixel group PG1 positioned in the first row may overlap the contact opening OP included in the third pixel group PG3 positioned in the second row in the fourth direction DR4, which is the diagonal direction. That is, the contact opening OP included in the first pixel group PG1 and the contact opening OP included in the third pixel group PG3 may be positioned at the center of the contact openings OP positioned in different rows and may be positioned on a line A-A′, which is an arbitrary extension line extending along the fourth direction DR4.

The contact opening OP included in the second pixel group PG2 positioned in the first row may overlap, or may be aligned with, the contact opening OP included in the fourth pixel group PG4 positioned in the second row along the third direction DR5. That is, the contact opening OP included in the second pixel group PG2 and the contact opening OP included in the fourth pixel group PG4 may be positioned at the center of the contact openings OP positioned in different rows, and may be positioned on a line B-B′, which is an arbitrary extension line extending along the fourth direction DR4.

In one or more embodiments, one pixel group PG may include a plurality of lighting areas LA corresponding to each of the plurality of pixels PX, and a non-lighting area NLA surrounding the lighting areas LA. The non-lighting area NLA may be positioned between the plurality of lighting areas LA. That is, the plurality of lighting areas LA may be surrounded by the non-lighting area NLA. Additionally, the plurality of lighting areas LA may correspond to each of the plurality of light-emitting areas EA above-described, and the non-lighting area NLA may correspond to the non-light-emitting area NEA.

The plurality of lighting areas LA may refer to areas that emit light emitted from the plurality of aforementioned light-emitting areas EA to the outside through the plurality of lighting area LA, and the non-lighting area NLA may refer to an area that blocks light emitted from the light-emitting area EA from being emitted to the outside.

Referring to FIG. 8, the lighting area LA and the non-lighting area NLA may be positioned on the second substrate SUB2, and may be defined by an overlapping part CFB where at least two color filters included in the color filter layer CFL overlap. That is, the lighting area LA may mean the areas between the overlapping parts CFB of the color filter layer CFL, and the non-lighting area NLA may mean the region where the overlapping parts CFB of the color filter layer CFL are positioned.

The color filters CF1, CF2, and CF3 may be positioned in each of the first to sixth lighting areas LA1, LA2, LA3, LA4, LA5, and LA6. For example, the first color filter CF1 that transmits the first color light may be positioned in the first lighting area LA1 and the fourth lighting area LA4, the second color filter CF2 that transmits the second color light may be positioned in the second lighting area LA2 and the fifth lighting area LA5, and the third color filter CF3 that transmits the third color light may be positioned in the fourth lighting area LA4 and the sixth lighting area LA6. The arrangement of the color filters CF1, CF2, and CF3 and the detailed description of the overlapping part CFB are described below together with FIG. 8.

In one or more embodiments, one pixel group PG may include the first lighting area LA1, the second lighting area LA2, the third lighting area LA3, the fourth lighting area LA4, the fifth lighting area LA5, and the sixth lighting area LA6, corresponding to the first to sixth pixels PX1, PX2, PX3, PX4, PX5, and PX6, respectively. That is, the first to sixth lighting areas LA1, LA2, LA3, LA4, LA5, and LA6 may overlap the first to sixth light-emitting areas EA1, EA2, EA3, EA4, EA5, and EA6, respectively.

In one or more embodiments, the planar area of each of the first to sixth lighting areas LA1, LA2, LA3, LA4, LA5, and LA6 may be larger than the planar area of each of the first to sixth light-emitting areas EA1, EA2, EA3, EA4, EA5, and EA6.

Accordingly, each of the first to sixth lighting areas LA1, LA2, LA3, LA4, LA5, and LA6 may entirely expose each of the first to sixth light-emitting areas EA1, EA2, EA3, EA4, EA5, and EA6.

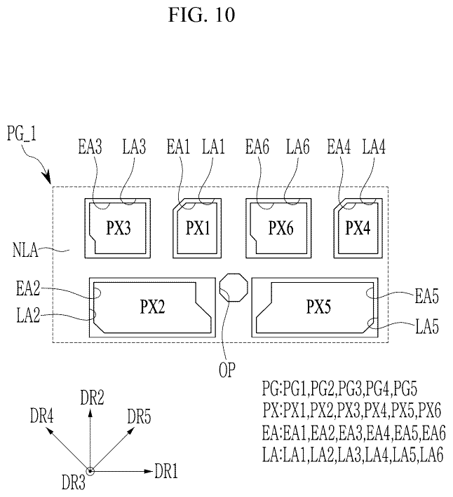

In one or more embodiments, the planar shape of each of the first to sixth lighting areas LA1, LA2, LA3, LA4, LA5, and LA6 may be different from the planar shape of each of the first to sixth light-emitting areas EA1, EA2, EA3, EA4, EA5, and EA6. For example, the planar shape of each of the first to sixth lighting areas LA1, LA2, LA3, LA4, LA5, and LA6 may have a rectangular shape. However, this is an example, and the planar shape of each lighting area LA may be a different shape, such as a rhombus, a pentagon, or an octagon, and may have various shapes and areas according to one or more embodiments. The detailed description therefor is described with reference to FIG. 10 to FIG. 13.

In one or more embodiments, among the first to sixth lighting areas LA1, LA2, LA3, LA4, LA5, and LA6 included in one pixel group PG, the first lighting area LA1, the second lighting area LA2, and the third light-emitting area EA3, which are positioned on one side with respect to the first direction DR1 with the contact opening OP as the center, have different areas on a plane, and the fourth lighting area LA4, the fifth lighting area LA5, and the sixth lighting area LA6 positioned on the other side with respect to the first direction DR1, may have different areas on a plane.

For example, as shown in FIG. 4 and FIG. 7, the area of the second lighting area LA2 may be larger than the areas of the first lighting area LA1 and the third lighting area LA3 included in one pixel group PG, and the area of the third lighting area LA3 may be larger than the area of the first lighting area LA1. That is, the area of the second lighting area LA2 may be the largest, and the area of the first lighting area LA1 may be the smallest.

Additionally, the area of the fifth lighting area LA5 may be larger than the areas of the fourth lighting area LA4 and the sixth lighting area LA6 included in one pixel group PG, and the area of the sixth lighting area LA6 may be larger than the area of the fourth lighting area LA4. That is, the area of the fifth lighting area LA5 may be the largest, and the area of the fourth lighting area LA4 may be the smallest.

Respective ones of some of the first to sixth lighting areas LA1, LA2, LA3, LA4, LA5, and LA6 included in one pixel group PG may have substantially the same area and planar shape.

For example, as shown in FIG. 4 and FIG. 6, the first lighting area LA1 included in one pixel group PG may have substantially the same area and shape as the fourth lighting area LA4 on a plane, and the third lighting area LA3 may have substantially the same area and shape as the sixth lighting area LA6 on a plane.

Additionally, unlike the second light-emitting area EA2 and the fifth light-emitting area EA5, which have symmetrical planar shapes, the second lighting area LA2 may have substantially the same area and shape as the fifth lighting area LA5 on a plane.

Accordingly, the planar shape of each of the plurality of lighting areas LA included in one of the plurality of pixel groups PG positioned in different rows may be substantially the same as the planar shape of each of the plurality of lighting areas LA included in another pixel group PG. For example, the planar shapes of the fourth lighting area LA4, the fifth lighting area LA5, and the sixth lighting area LA6 included in the first pixel group PG1 positioned in the first row may be respectively substantially the same as the planar shapes of the first lighting area LA1, the second lighting area LA2, and the third lighting area LA3 included in the third pixel group PG3 positioned in the second row. As another example, the planar shapes of the first lighting area LA1, the second lighting area LA2, and the third lighting area LA3 included in the second pixel group PG2 positioned in the first row may be respectively substantially the same as the planar shape of the fourth lighting area LA4, the fifth lighting area LA5, and the sixth lighting area LA6 included in the third pixel group PG3 positioned in the second row.

In one or more embodiments, the plurality of lighting areas LA included in one pixel group PG may not overlap the contact opening OP included in the pixel group PG in the third direction DR3, which is a vertical direction. For example, the second lighting area LA2 and the fifth lighting area LA5, which are positioned apart from each other in the first direction DR1 with the contact opening OP in between, may not overlap the contact opening OP in the third direction DR3, which is a vertical direction. However, the present disclosure is not limited to this, and may be changed in various ways. For example, as the second lighting area LA2 and the fifth lighting area LA5 are further extended and positioned toward the contact opening OP in the first direction DR1, a part of the second lighting area LA2 and a part of the fifth lighting area LA5 may overlap the contact opening OP in the third direction DR3, which is a vertical direction.

Hereinafter, the cross-sectional structure of the display device according to one or more embodiments is described with further reference to FIG. 8 and FIG. 9 along with FIG. 1 to FIG. 7.

Hereinafter, the cross-section of the first to third light-emitting areas EA1, EA2, and EA3 and the first to third lighting areas LA1, LA2, and LA3 included in the first to third pixels PX1, PX2, and PX3 included in one pixel group PG is described, and this description is substantially equally applicable to the fourth to sixth light-emitting areas EA4, EA5, and EA6 and the fourth to sixth lighting areas LA4, LA5, and LA6 included in the fourth to sixth pixels PX4, PX5, and PX6.

A display device 1000 according to one or more embodiments may include a display unit DC and a color converter CC that overlap.

The display unit DC according to one or more embodiments may include a first substrate SUB1, a plurality of transistors positioned on the first substrate SUB1 and comprising a gate electrode GE, a semiconductor layer ACT, a source electrode SE, and a drain electrode DE, a plurality of light-emitting elements ED, a common voltage wiring VL positioned on the first substrate SUB1, and an encapsulation layer ENC positioned on the plurality of light-emitting elements ED (as used herein, “positioned on” may mean “over”).

The first substrate SUB1 may include an insulating material, and may include a transparent material. For example, the first substrate SUB1 may include a plastic, such as glass, quartz, or polyimide. The first substrate SUB1 may be a rigid substrate or may have flexible characteristics, such as bending, folding, or rolling.

The display unit DC according to one or more embodiments may further include a buffer layer BF positioned on the first substrate SUB1.

The buffer layer BF may be positioned on the first substrate SUB1. The buffer layer BF is positioned between the first substrate SUB1 and the semiconductor layer ACT, and blocks impurities from the first substrate SUB1 during the crystallization process to form a polycrystalline silicon, thereby improving the characteristics of the polycrystalline silicon, and planarizing the first substrate SUB1, thereby relieving or reducing stress on the semiconductor layer ACT positioned on the buffer layer BF.

The buffer layer BF may be an inorganic insulating material or an organic insulating material including silicon oxide (SiOx), silicon nitride (SiNx), silicon oxynitride (SiOxNy), etc., and may be a single layer or multiple layers. According to one or more embodiments, the buffer layer BF may be omitted.

The semiconductor layer ACT may be positioned on the buffer layer BF. The semiconductor layer ACT may include semiconductor materials, such as amorphous silicon, polycrystalline silicon, and oxide semiconductor. The semiconductor layer ACT may include a channel area C, a source area S, and a drain area D.

The source area S and the drain area D may each be positioned on either side of the channel area C. The channel area C may be an intrinsic semiconductor with no impurity doping, and the source area S and drain area D may be impurity semiconductors that are doped with conductive impurities and have a conductivity.

In one or more embodiments, the semiconductor layer ACT may include an oxide semiconductor, and in this case, a separate protective layer may be further included to protect the oxide semiconductor material, which is vulnerable to external environments, such as high temperatures.

The display unit DC according to one or more embodiments may further include a gate-insulating layer GI positioned on the semiconductor layer ACT.

The gate-insulating layer GI may be positioned on the semiconductor layer ACT. The gate-insulating layer GI may include an inorganic insulating material or an organic insulating material including silicon oxide (SiOx), silicon nitride (SiNx), silicon oxynitride (SiOxNy), etc., and may be a single layer or multiple layers.

A first conductive layer including a gate electrode GE may be positioned on the gate-insulating layer GI. The first conductive layer may include at least one metal or an alloy of metals, such as aluminum (AI), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), and may be comprising a single layer or multiple layers.

The display unit DC according to one or more embodiments may further include an interlayer insulating layer IL1 and a passivation layer IL2 sequentially positioned on the gate electrode GE.

The interlayer insulating layer IL1 may be positioned on the gate electrode GE. The interlayer insulating layer IL1 may include an inorganic insulating material or an organic insulating material including silicon oxide (SiOx), silicon nitride (SiNx), silicon oxynitride (SiOxNy), etc., and may be a single layer or multiple layers.

A second conductive layer including a source electrode SE, a drain electrode DE, and a common voltage wiring VL may be positioned on the interlayer insulating layer IL1. The source electrode SE and the drain electrode DE may be electrically connected to the source area S and the drain area D of the semiconductor layer ACT, respectively, through contact holes included in the interlayer insulating layer IL1.

The common voltage wiring VL may be applied with a common voltage described above (e.g., common voltage ELVSS in FIG. 3). The common voltage wiring VL may be extended along the second direction DR2 over the interlayer insulating layer IL1. In FIG. 9, the common voltage wiring VL is depicted as being positioned on the interlayer insulating layer IL1, but the common voltage wiring VL may be positioned on another conductive layer.

A passivation layer IL2 may be positioned on the interlayer insulating layer IL1, the source electrode SE, and the drain electrode DE. Because the passivation layer IL2 covers and planarizes the interlayer insulating layer IL1, the source electrode SE, and the drain electrode DE, the first electrode E1 can be formed on the passivation layer IL2 without a step.

The passivation layer IL2 may include an organic insulating material or an inorganic insulating material, such as a polymer derivative, an acryl-based polymer, an imide-based polymer, polyimide, polyamide, an acryl-based polymer, and/or a siloxane-based polymer.

A light-emitting element ED may be positioned on the passivation layer IL2. The light-emitting element ED may include a first electrode E1, a light-emitting layer EML, and a second electrode E2.

A third conductive layer including the first electrode E1 and a connecting electrode CL may be positioned on the passivation layer IL2. The first electrode E1 may be electrically connected to the drain electrode DE through a contact hole of the passivation layer IL2.

The driving transistor, which consists of the gate electrode GE, the semiconductor layer ACT, the source electrode SE, and the drain electrode DE, may be electrically connected to the first electrode E1, and may supply a driving current to the light-emitting element ED, which will be described later.

According to some embodiments, the display device may further include, in addition to the driving transistor illustrated in FIG. 8, a switching transistor connected to a data line for transmitting a data voltage in response to a scan signal, a compensation transistor connected to the driving transistor for responding to the scan signal to compensate for a threshold voltage of the driving transistor, etc.

The connection electrode CL positioned in the passivation layer IL2 may be electrically connected to the common voltage wiring VL. That is, a part of the connection electrode CL may be connected to the common voltage wiring VL through a contact hole penetrating at least one insulating layer positioned between the common voltage wiring VL and the connection electrode CL. For example, a part of the connection electrode CL may be electrically connected to the common voltage wiring VL through the contact hole CH of the passivation layer IL2 positioned on the common voltage wiring VL. However, this is an example, and the connection electrode CL may be positioned on another conductive layer, in which case, a part of the connection electrode CL may be connected to the common voltage wiring VL through a contact hole penetrating at least one insulating layer positioned between the other conductive layer and the common voltage wiring VL.

A pixel definition layer PDL may be positioned on the passivation layer IL2 and the first electrode E1. The pixel definition layer PDL overlaps the first electrode E1 and may include, or define, pixel openings that define the light-emitting areas EA1, EA2, and EA3. The first electrode E1 may have substantially the same or similar planar shape as the light-emitting areas EA described above with reference to FIG. 4 and FIG. 5.

The pixel definition layer PDL may include a contact opening OP positioned over a part of the connection electrode CL in the non-light-emitting area NEA. The contact opening OP positioned on a part of the connection electrode CL may be positioned spaced apart from, and not overlapping, the contact hole CH of the passivation layer IL2 positioned on a part of the common voltage wiring VL.

The pixel definition layer PDL may include organic insulating materials, such as polyimide, polyamide, acryl resin, benzocyclobutene, and phenol resin, or inorganic insulating materials, such as silica.

The light-emitting layer EML may be positioned on the first electrode E1, which is positioned within the pixel opening defining the light-emitting areas EA1, EA2, and EA3.

In FIG. 8, the light-emitting layer EML is depicted as being positioned only within the pixel opening of the pixel definition layer PDL that defines the light-emitting areas EA1, EA2, and EA3, but the arrangement of the light-emitting layer EML is not limited thereto and may be changed in various ways. That is, a part of the light-emitting layer EML may be positioned within the light-emitting areas EA1, EA2, and

EA3, and the remaining parts may be positioned on the side of the pixel definition layer PDL or on the pixel definition layer PDL.

Additionally, the light-emitting layer EML may include a light-emitting layer opening EOP that is positioned on a part of the connection electrode CL within the contact opening OP defined by the pixel definition layer PDL, and overlaps a part of the connection electrode CL.

The light-emitting layer opening EOP of the light-emitting layer EML may overlap at least a part of the contact opening OP of the pixel definition layer PDL. For example, as shown in FIG. 9, the light-emitting layer opening EOP of the light-emitting layer EML may be positioned within the edge of the contact opening OP of the pixel definition layer PDL. That is, a part of the light-emitting layer EML may be positioned within the contact opening OP of the pixel definition layer PDL, and the area of the light-emitting layer opening EOP of the light-emitting layer EML may be smaller than the area of the contact opening OP of the pixel definition layer PDL.

As another example, unlike that illustrated in FIG. 9, the edge of the light-emitting layer opening EOP of the light-emitting layer EML may be arranged to be substantially aligned with the edge of the contact opening OP of the pixel definition layer PDL. That is, because the light-emitting layer opening EOP of the light-emitting layer EML and the contact opening OP of the pixel definition layer PDL have substantially the same area, the light-emitting layer EML may not be positioned within the contact opening OP of the pixel definition layer PDL.

In one or more embodiments, as a method of forming the light-emitting layer opening EOP of the light-emitting layer EML, it may be formed by forming the light-emitting layer EML within the contact opening OP of the pixel definition layer PDL, and then removing a part of the light-emitting layer EML that overlaps the connection electrode CL by using a laser drilling process. However, the method of forming the light-emitting layer opening EOP is not limited to this and may be changed in various ways.

In some embodiments, after forming the light-emitting layer EML on the pixel definition layer PDL, the light-emitting layer EML and the pixel definition layer PDL positioned on the connection electrode CL may be removed together using a process, such as laser drilling, so that the contact opening OP of the pixel definition layer PDL and the light-emitting layer opening EOP of the light-emitting layer EML may be concurrently or substantially simultaneously formed.

Also, in FIG. 9, the pixel definition layer PDL is depicted as being positioned directly above the connection electrode CL, but if the connection electrode CL is positioned on another conductive layer, a plurality of insulating layers may be positioned between the connection electrode CL and the pixel definition layer PDL. In this case, a contact hole may be formed by removing a plurality of insulating layers other than the light-emitting layer EML using a process, such as laser drilling, to expose a part of the connection electrode CL.

The light-emitting layer EML may contain a low-molecular organic material or a polymer organic material, such as PEDOT (Poly 3,4-ethylenedioxythiophene). The light-emitting layer EML may further include one or more of a hole injection layer (HIL), a hole transport layer (HTL), an electron transport layer (ETL), and/or an electron injection layer (EIL), and may be multilayer.

The second electrode E2 may be positioned on the light-emitting layer EML. The second electrode E2 may be formed by a single conductor across the plurality of pixels PX1, PX2, and PX3.

Additionally, a part of the second electrode E2 is positioned within the contact opening OP of the pixel definition layer PDL in the non-light-emitting area NEA, and may be electrically connected to the connection electrode 195 through the light-emitting layer opening EOP of the light-emitting layer EML. The second electrode E2 may be electrically connected to the common voltage wiring VL through the connection electrode CL, and may receive the common voltage (e.g., common voltage ELVSS in FIG. 3).

The first electrode E1 may be an anode, which is a hole injection electrode, and the second electrode E2 may be a cathode, which is an electron injection electrode. However, the present disclosure is not limited thereto, and according to a driving method of the display device, the first electrode E1 may become the cathode and the second electrode E2 may become the anode.

Holes and electrons are injected into the light-emitting layer EML from the first electrode E1 and the second electrode E2, respectively, and light-emitting occurs when the exciton formed by combining the injected holes and electrons drops from the excited state to the ground state.

The light-emitting element ED according to one or more embodiments may include a plurality of light-emitting units. Each light-emitting unit may include a light-emitting layer. The light-emitting element ED may be a tandem structure light-emitting element. The plurality of light-emitting layers may emit the same light or may emit a different light. For example, the light-emitting element ED may emit light that is a mixture of a green light and a blue light, or may emit a blue light.

The encapsulation layer ENC may be positioned on the second electrode E2. The encapsulation layer ENC may block an inflow of external moisture and oxygen by covering and sealing the light-emitting element ED. The encapsulation layer ENC may include a plurality of layers, and may be formed as a composite film including alternately stacked inorganic and organic films. For example, the encapsulation layer ENC may include a triple layer including sequentially stacked inorganic film EIL1, organic film EOL, and inorganic film EIL2. However, this is an example, and the type and number of films included in the encapsulation layer ENC are not limited to this, and may be changed in various ways.

The color converter CC may be positioned on the encapsulation layer ENC. That is, the encapsulation layer ENC may be positioned between the display unit DC and the color converter CC.

According to one or more embodiments, the color converter CC may include a second substrate SUB2, a color filter layer CFL positioned on the second substrate SUB2, and a partition wall BK positioned on the color filter layer CFL and including or defining partition wall openings BOP1, BOP2, and BOP3, a transmitting layer TL positioned within the partition wall openings BOP1, BOP2, and BOP3, and color conversion layers CCL1 and CCL2.

The second substrate SUB2 of the color converter CC may overlap the first substrate SUB1 of the display unit DC in the third direction DR3, which is the vertical direction. The second substrate SUB2 may include an insulating material, and may include a transparent material. For example, the second substrate SUB2 may include a plastic, such as glass, quartz, or polyimide. The second substrate SUB2 may be a rigid substrate, or may have flexible characteristics, such as the ability for bending, folding, or rolling.

The color filter layer CFL may be positioned between the second substrate SUB2 and the encapsulation layer ENC of the display unit DC. As described above, the color filter layer CFL may include a plurality of color filters CF. For example, the color filter CF may include a first color filter CF1 that transmits a first color light, a second color filter CF2 that transmits a second color light, and a third color filter CF3 that transmits a third color light.

The color filter layer CFL may include an overlapping part CFB in which at least two of the first color filter CF1, the second color filter CF2, and the third color filter CF3 overlap. The overlapping part CFB may act as a light-blocking member. As described above, the overlapping part CFB of the color filter layer CFL

defines the lighting areas LA1, LA2, and LA3 that overlap the light-emitting areas EA1, EA2, and EA3 of the display unit DC. That is, the lighting areas LA1, LA2, and LA3 may be defined by the edges of the overlapping part CFB of the color filter layer CFL. In other words, the lighting areas LA1, LA2, and LA3 may mean the region between the overlapping part CFB of the color filter layer CFL.

The first color filter CF1 may correspond to the first lighting area LA1, the second color filter CF2 may correspond to the second lighting area LA2, and the third color filter CF3 may correspond to the third lighting area LA3.

The overlapping part CFB of the color filter layer CFL may surround the lighting areas LA1, LA2, and LA3, and may define the non-lighting area NLA that overlaps the non-light-emitting area NEA of the display unit DC. The overlapping part CFB of the pixel definition layer PDL and the color filter layer CFL of the display unit DC may be positioned in the non-lighting area NLA. That is, the pixel definition layer PDL of the display unit DC and the overlapping part CFB of the color filter layer CFL of the color converter CC can overlap.

The first color filter CF1 may overlap the transmitting layer TL. The first color filter CF1 may transmit the blue light that passes through the transmitting layer TL, and may absorb the light of the remaining wavelengths, thereby increasing the purity of the blue light emitted to the outside of the display device.

The second color filter CF2 may overlap the first color conversion layer CCL1. The second color filter CF2 may transmit the green light that passes through the first color conversion layer CCL1, and may absorb the light of the remaining wavelengths, thereby increasing the purity of the green light emitted to the outside of the display device.

The third color filter CF3 may overlap the second color conversion layer CCL2. The third color filter CF3 may transmit the red light that passes through the second color conversion layer CCL2, and may absorb the light of the remaining wavelengths, thereby increasing the purity of the red light emitted outside the display device.

The partition wall BK may be positioned between the color filter layer CFL and the encapsulation layer ENC of the display unit DC. The partition wall BK may overlap the non-light-emitting area NEA of the display unit DC and the non-lighting area NLA of the color converter CC. That is, the partition wall BK may overlap the pixel definition layer PDL of the display unit DC and the overlapping part CFB of the color filter layer CFL of the color converter CC.

The partition wall BK may include a first partition wall opening BOP1, a second partition wall opening BOP2, and a third partition wall opening BOP3 that overlap each of the light-emitting areas EA1, EA2, and EA3 of the display unit DC and the lighting areas LA1, LA2, and LA3 of the color converter CC.

The width and/or depth of the first to third partition wall openings BOP1, BOP2, and BOP3 may be different or may be substantially the same. Each of the first to third partition wall openings BOP1, BOP2, and BOP3 may be larger than the width of each of the first to third light-emitting areas EA1, EA2, and EA3 and the width of each of the first to third lighting areas LA1, LA2, and LA3.

The transmitting layer TL overlaps the first light-emitting area EA1 and the first lighting area LA1, may be positioned in the first partition wall opening BOP1, and may transmit the light incident from the light-emitting element ED. The light incident from the light-emitting element ED may be the blue light alone, or may be a mixture of the blue light and the green light. Alternatively, it may include all of the blue, green, and red light.

The transmitting layer TL may include a polymer resin, and a plurality of scatterers SC included in the polymer resin.

The first color conversion layer CCL1 overlapping the second light-emitting area EA2 and the second lighting area LA2 may be positioned in the second partition wall opening BOP2, and the first color conversion layer CCL1 may convert the light incident from the light-emitting element ED to green. The first color conversion layer CCL1 may include a plurality of first quantum dots QD1 and a plurality of scatterers SC.

The second color conversion layer CCL2, which overlaps the third light-emitting area EA3 and the third lighting area LA3, may be positioned at the third partition wall opening BOP3, and the second color conversion layer CCL2 may convert the light incident from the light-emitting element ED to red. The second color conversion layer CCL2 may include a plurality of second quantum dots QD2 and a plurality of scatterers SC.

A plurality of scatterers SC may improve optical efficiency by scattering light incident on the first color conversion layer CCL1, the second color conversion layer CCL2, and the transmitting layer TL.

The scatterer SC may be one or more selected from the group including SiO₂, BaSO₄, Al₂O₃, ZnO, ZrO₂, and/or TiO₂. For example, the scatterer SC may include TiO₂, but is not limited thereto.

Each of the first quantum dot QD1 and the second quantum dot QD2 (hereinafter referred to as semiconductor nanocrystals) may independently include a Group II-VI compound, a Group III-V compound, a Group IV-VI compound, a Group IV element or compound, a Group I-III-VI compound, a Group II-III-VI compound, a Group I-II-IV-VI compound, or a combination thereof. The quantum dots may not include cadmium.

The Group II-VI compound may be selected from a group including a binary compound selected from a group including CdSe, CdTe, ZnS, ZnSe, ZnTe, ZnO, HgS, HgSe, HgTe, MgSe, MgS, and/or a mixture thereof; a ternary compound selected from a group including AglnS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or a mixture thereof; and a quaternary compound selected from a group including HgZnTeS, CdZnSeS, CdZnSeTe, CdZnSTe, CdHgSeS, CdHgSeTe, CdHgSTe, HgZnSeS, HgZnSeTe, HgZnSTe, and/or a mixture thereof. The Group II-VI compound may further include a Group III metal.

The Group III-V compound may be selected from a group including a binary compound selected from a group including GaN, GaP, GaAs, GaSb, AlN, AlP, AlAs, AlSb, InN, InP, InAs, InSb, and/or a mixture thereof; a ternary compound selected from a group including GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and/or a mixture thereof; and a quaternary compound selected from a group including GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and/or a mixture thereof. The Group III-V compound may further include a Group II metal (e.g., InZnP).

The Group IV-VI compound may be selected from a group including a binary compound selected from a group including SnS, SnSe, SnTe, PbS, PbSe, PbTe, and/or a mixture thereof; a ternary compound selected from a group including SnSeS, SnSeTe, SnSTe, PbSeS, PbSeTe, PbSTe, SnPbS, SnPbSe, SnPbTe, and/or a mixture thereof; and a quaternary compound selected from a group including SnPbSSe, SnPbSeTe, SnPbSTe, and/or a mixture thereof.

The Group IV element or compound may be selected from a group including: a single-element compound selected from a group including Si, Ge, and/or combinations thereof; and a binary element compound selected from a group including SiC, SiGe, and/or combinations thereof.

An example of the Group I-III-VI compound includes CuInSe2, CuInS2, CuInGaSe, and/or CuInGaS, but is not limited thereto. An example of the Group I-II-IV-VI compound includes CuZnSnSe and/or CuZnSnS, but is not limited thereto. The Group IV element or compound may be selected from a group including: a single-element compound selected from a group including Si, Ge, and/or combinations thereof; and a binary-element compound selected from a group including SiC, SiGe, and/or combinations thereof.

The Group II-III-VI compound may be selected from a group including ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, and/or combinations thereof.

The Group I-II-IV-VI compound may be selected from CuZnSnSe and CuZnSnS, and is not limited thereto.

In one or more embodiments, the quantum dots may not include cadmium. The quantum dots may include a semiconductor nanocrystal based on a Group III-V compound including indium and phosphorus. The Group III-V compound may further include zinc. The quantum dots may include a semiconductor nanocrystal based on a Group II-VI compound including a chalcogen element (e.g., sulfur, selenium, tellurium, or combinations thereof) and zinc.

In the quantum dots, the binary compound, the ternary compound, or the quaternary compound as described above may be present in the particle at a uniform concentration or in the same particle of which a concentration distribution may be partially divided into different states. Also, they may have a core/shell structure in which one quantum dot surrounds another quantum dot. The interface between the core and the shell may have a concentration gradient in which the concentration of the elements present in the shell decreases toward the center.

In some embodiments, the quantum dots may have a core-shell structure including a core including the above-described nanocrystal and a shell surrounding the core. The shell of the quantum dot may function as a protective layer for maintaining the semiconductor characteristics by reducing or preventing a chemical modification of the core and/or a charging layer for imparting electrophoretic characteristics to the quantum dot. The shell can be single-layered or multi-layered. An interface between the core and the shell may have a concentration gradient in which the concentration of elements present in the shell decreases toward the center. Examples of the shell of the quantum dot include a metal or non-metal oxide, a semiconductor compound, or a combination thereof.

For example, the metal or non-metal oxide may be exemplified as a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or a ternary compound, such as MgAl₂O₄, CoFe₂O₄, NiFe₂O₄, and CoMn₂O₄, but the present disclosure is not limited thereto.

Also, the semiconductor compound may be exemplified as CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, or AlSb, but the present disclosure is not limited thereto.

An interface between the core and the shell may have a concentration gradient, such that a concentration of an element existing in the shell is gradually reduced in a direction toward the center thereof. In addition, the semiconductor nanocrystals may have a structure including one semiconductor nanocrystal core and multi-layered shells surrounding the core. In one or more embodiments, the multi-layered shells may have two or more layers (e.g., two, three, four, five, or more layers). Two adjacent layers of the shell may have a single composition or different compositions. In the multi-layered shell, each layer may have a composition that varies along the radius.

The quantum dots may have a full width at half maximum (FWHM) of about 45 nm or less, about 40 nm or less, or about 30 nm or less, and may improve color purity or color reproducibility in this range. Also, because light emitted through the quantum dots is emitted in all directions, a viewing angle may be improved.

In the quantum dots, the shell material and the core material may have different energy bandgaps. For example, the energy bandgap of the shell material may be greater than that of the core material. Alternatively, the energy bandgap of the shell material may be less than that of the core material. The quantum dots may have a multi-layered shell. In the multi-layered shell, the energy bandgap of the outer layer may be greater than the energy bandgap of the inner layer (e.g., the layer closer to the core). In the multi-layered shell, the energy bandgap of the outer layer may be less than the energy bandgap of the inner layer.

The quantum dots may control an absorption/emission wavelength by adjusting a composition and a size thereof. A maximum peak emission wavelength of the quantum dot may be an ultraviolet (UV) to infrared wavelength or a wavelength of greater than the above wavelength range.

The quantum dots may include an organic ligand (e.g., having a hydrophobic moiety or a hydrophilic moiety). The organic ligand moiety may be bound to a surface of the quantum dots. The organic ligand may include RCOOH, RNH₂, R₂NH, R₃N, RSH, R₃PO, R₃P, ROH, RCOOR, RPO(OH)₂, RHPOOH, R₂POOH, or a combination thereof, wherein R is independently a C3 to C40 substituted or unsubstituted aliphatic hydrocarbon group, such as a C3 to C40 (e.g., C5 or greater and C24 or less) substituted or unsubstituted alkyl, or a substituted or unsubstituted alkenyl, a C6 to C40 (e.g., C6 or greater and C20 or less) substituted or unsubstituted aromatic hydrocarbon group, such as a substituted or unsubstituted C6 to C40 aryl group, or a combination thereof.

Examples of the organic ligand may be a thiol compound, such as methane thiol, ethane thiol, propane thiol, butane thiol, pentane thiol, hexane thiol, octane thiol, dodecane thiol, hexadecane thiol, octadecane thiol, or benzyl thiol; an amine, such as methane amine, ethane amine, propane amine, butane amine, pentyl amine, hexyl amine, octyl amine, nonylamine, decylamine, dodecyl amine, hexadecyl amine, octadecyl amine, dimethyl amine, diethyl amine, dipropyl amine, tributylamine, or trioctylamine; a carboxylic acid compound, such as methanoic acid, ethanoic acid, propanoic acid, butanoic acid, pentanoic acid, hexanoic acid, heptanoic acid, octanoic acid, dodecanoic acid, 47exadecenoic acid, octadecanoic acid, oleic acid, or benzoic acid; a phosphine compound, such as methyl phosphine, ethyl phosphine, propyl phosphine, butyl phosphine, pentyl phosphine, octylphosphine, dioctyl phosphine, tributylphosphine, or trioctylphosphine; a phosphine compound or an oxide compound thereof such methyl phosphine oxide, ethyl phosphine oxide, propyl phosphine oxide, butyl phosphine oxide pentyl phosphine oxide, tributylphosphine oxide, octylphosphine oxide, dioctyl phosphine oxide, or trioctylphosphine oxide; a diphenyl phosphine, triphenyl phosphine compound, or an oxide compound thereof; a C5 to C20 alkyl phosphonic acid, such as hexylphosphinic acid, octylphosphinic acid, dodecanephosphinic acid, tetradecanephosphinic acid, hexadecanephosphinic acid, octadecanephosphinic acid; and/or the like, but are not limited thereto. The quantum dots may include a hydrophobic organic ligand alone or in a mixture of at least one type. The hydrophobic organic ligand may not include a photopolymerizable moiety (e.g., an acrylate group, a methacrylate group, etc.).

The color converter CC may further include a second insulating layer IL4 and a third insulating layer IL5 sequentially positioned between the color filter layer CFL and the partition wall BK, between the color filter layer CFL and the transmitting layer TL, and between the color filter layer CFL and the color conversion layers CCL1 and CCL2.

The third insulating layer IL5 may be positioned between the second insulating layer IL4 and the color filter layer CFL, and may planarize the color filter layer CFL. The third insulating layer IL5 may include, for example, an organic material, or an inorganic material, such as silicon nitride (SiNx), silicon oxide SiO₂, or silicon oxynitride.

The second insulating layer IL4 may entirely cover the partition wall BK, transmitting layer TL, and color conversion layers CCL1 and CCL2. The second insulating layer IL4 may include silicon nitride (SiNx), silicon oxide SiO₂ or silicon oxynitride. According to one or more embodiments, the second insulating layer IL4 may be omitted.

The color converter CC may further include a first insulating layer IL3 and a filling layer FL sequentially positioned between the partition wall BK and the encapsulation layer ENC of the display unit DC, between the transmitting layer TL and the encapsulation layer ENC of the display unit DC, and between the color conversion layers CCL1 and CCL2 and the encapsulation layer ENC of the display unit DC.

The first insulating layer IL3 may entirely cover the partition wall BK, the first color conversion layer CCL1, the second color conversion layer CCL2, and the transmitting layer TL. The first insulating layer IL3 may extend conformally along the surfaces of the partition wall BK, the first color conversion layer CCL1, the second color conversion layer CCL2, and the transmitting layer TL. The first insulating layer IL3 may include, for example, inorganic materials.

The filling layer FL may be positioned between the first insulating layer IL3 and the encapsulation layer ENC of the display unit DC. The filling layer FL may fill the gap region between the color converter CC and the display unit DC, thereby connecting the color converter CC and the display unit DC. The filler layer FL may include a filler. According to one or more embodiments, the region where the filler layer FL is positioned may be filled with air.

According to one or more embodiments of the display device, as the plurality of light-emitting areas EA included in each of the plurality of pixels PX are arranged so as to reduce or minimize the number of the contact openings OP positioned in the non-light-emitting area NEA, the areas of the light-emitting areas EA and the areas of the light-emitting elements ED positioned in each of the light-emitting areas EA may relatively increase.

Accordingly, the luminous efficiency and lifespan of the light-emitting element ED are improved, thereby providing the display device with improved luminescence characteristics.

Hereinafter, the display devices according to various embodiments are described with reference to FIG. 10 to FIG. 13. In the embodiments below, the same components as those described previously are referred to by the same reference numerals, and duplicate descriptions are omitted or simplified, with explanations focusing on differences.

FIG. 10 to FIG. 13 are plan views illustrating a part of a display device according to some embodiments. FIG. 10 to FIG. 13 are plan views illustrating one pixel group PG among a plurality of pixel groups PG included in a display device according to some embodiments.

The pixel groups PG_1, PG_2, PG_3, and PG_4 according to the embodiments respectively illustrated in FIG. 10 to FIG. 13 differ from the pixel groups PG in that they include pixels PX having substantially the same in-plane shape of the overlapping light-emitting area EA and the lighting area LA.

The contents described above with reference to FIG. 4 and FIG. 5 may be applied substantially the same to the planar arrangement and shape of the first to sixth light-emitting areas EA1, EA2, EA3, EA4, EA5, and EA6 of the first to sixth pixels PX1, PX2, PX3, PX4, PX5, and PX6 included in the pixel groups PG_1, PG_2, PG_3, and PG_4 according to the embodiments illustrated in FIG. 10 to FIG. 13 so the description thereof is omitted, and the explanation is centered on the planar shapes of the first to sixth lighting areas LA1, LA2, LA3, LA4, LA5, and LA6.

For example, referring to FIG. 10, the first pixel PX1 and the fourth pixel PX4 included in the pixel group PG_1 may display the first color, the second pixel PX2 and the fifth pixel PX5 may display the second color, and the third pixel PX3 and the sixth pixel PX6 may display the third color.

Here, the first color may be blue, the second color may be green, and the third color may be red. However, this is an example only, and the first color, second color, and third color may be changed in various ways.

The first light-emitting area EA1 and the first lighting area LA1 of the first pixel PX1 included in the pixel group PG_1 may have substantially the same planar shape, and the fourth light-emitting area EA4 and the fourth lighting area LA4 of the fourth pixel PX4 may have substantially the same planar shape. The first lighting area LA1 and the fourth lighting area LA4 may have substantially the same planar shape.

In one or more embodiments, each of the first lighting area LA1 and the fourth lighting area LA4 may have a part of a corner chamfered similarly to the first light-emitting area EA1 and the fourth light-emitting area EA4. However, this is an example, and the planar shape of each of the first lighting area LA1 and the fourth lighting area LA4 may be changed in various ways depending on the planar shape of each of the first light-emitting area EA1 and the fourth light-emitting area EA4.

The second light-emitting area EA2 and the second lighting area LA2 of the second pixel PX2 included in the pixel group PG_1 may have different planar shapes, and the fifth light-emitting area EA5 and the fifth lighting area LA5 of the fifth pixel PX5 may have different planar shapes. The second lighting area LA2 and the fifth lighting area LA5 may have substantially the same planar shape.

In addition, the third light-emitting area EA3 and the third lighting area LA3 of the third pixel PX3 included in the pixel group PG_1 may have different planar shapes, and the sixth light-emitting area EA6 and the sixth lighting area LA6 of the sixth pixel PX6 may have different planar shapes. The third lighting area LA3 and the sixth lighting area LA6 may have substantially the same planar shape.

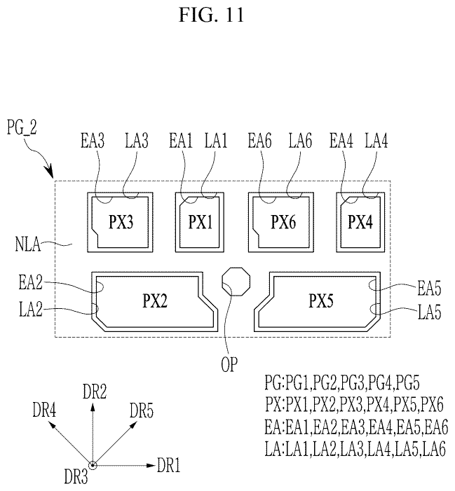

Referring to FIG. 11, the second light-emitting area EA2 and the second lighting area LA2 of the second pixel PX2 included in the pixel group PG_2 may have substantially the same planar shape, and the fifth light-emitting area EA5 and the fifth lighting area LA5 of the fifth pixel PX5 may have substantially the same planar shape.

In one or more embodiments, because the second light-emitting area EA2 and the fifth light-emitting area EA5 have the plane mirror-symmetric shape with the contact opening OP as a reference/point of symmetry, the second lighting area LA2 and the fifth lighting area LA5, which respectively correspond to the second light-emitting area EA2 and the fifth light-emitting area EA5, may have the plane mirror-symmetrical shape with the contact opening OP as a reference.

In one or more embodiments, each of the second lighting area LA2 and the fifth lighting area LA5 may have a corner part facing the contact opening OP chamfered along the side surface of the contact opening OP, similar to the second light-emitting area EA2 and the fifth light-emitting area EA5. However, this is an example, and the planar shape of each of the second lighting area LA2 and the fifth lighting area LA5 may be variously changed depending on the planar shape of each of the second light-emitting area EA2 and the fifth light-emitting area EA5.

The first light-emitting area EA1 and the first lighting area LA1 of the first pixel PX1 included in the pixel group PG_2 may have different planar shapes, and the fourth light-emitting area EA4 and the fourth lighting area LA4 of the fourth pixel PX4 may have different planar shapes. The first lighting area LA1 and the fourth lighting area LA4 may have substantially the same shape in plane.

The third light-emitting area EA3 and the third lighting area LA3 of the third pixel PX3, and the sixth light-emitting area EA6 and the sixth lighting area LA6 of the sixth pixel PX6, which are included in the pixel group PG_2, are substantially the same as the one or more embodiments corresponding to FIG. 10, so the description thereof is omitted.

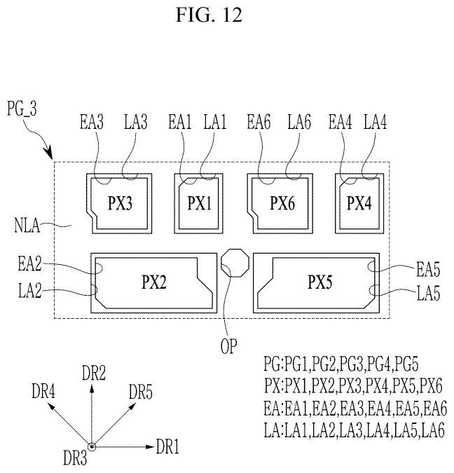

Referring to FIG. 12, the third light-emitting area EA3 and the third lighting area LA3 of the third pixel PX3 included in the pixel group PG_3 may have substantially the same planar shape, and the sixth light-emitting area EA6 and the sixth lighting area LA6 of the sixth pixel PX6 may have substantially the same planar shape. The third lighting area LA3 and the sixth lighting area LA6 may have substantially the same planar shape.

In one or more embodiments, each of the third lighting area LA3 and the sixth lighting area LA6 may have a part of a corner chamfered similarly to the third light-emitting area EA3 and the sixth light-emitting area EA6. However, this is an example, and the planar shape of each of the third lighting area LA3 and the sixth lighting area LA6 may be variously changed depending on the planar shape of each of the third light-emitting area EA3 and the sixth light-emitting area EA6.

The first light-emitting area EA1 and the first lighting area LA1 of the first pixel PX1, and the fourth light-emitting area EA4 and the fourth lighting area LA4 of the fourth pixel PX4, which are included in the pixel group PG_3, are substantially the same as those in the one or more embodiments corresponding to FIG. 11, so the description thereof is omitted.

In addition, the second light-emitting area EA2 and the second lighting area LA2 of the second pixel PX2 included in the pixel group PG_3, and the fifth light-emitting area EA5 and the fifth lighting area LA5 of the fifth pixel PX5, are substantially the same as those in the one or more embodiments corresponding to FIG. 10, so the description thereof is omitted.

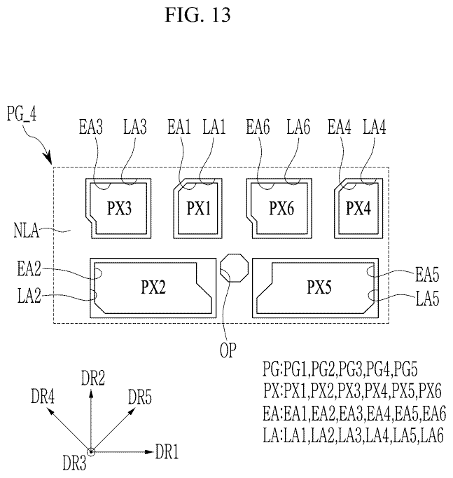

According to the pixel group PG_4 according to the one or more embodiments corresponding to FIG. 13, unlike the pixel groups PG_1, PG_2, and PG_3 according to the embodiments illustrated in FIG. 10 to FIG. 12, there is a difference in that the number of the pixels PX in the pixel group PG_4 whose planar shapes of the light-emitting area EA and the lighting area LA are substantially the same is greater than the number of the pixels PX whose planar shapes of the light-emitting area EA and the lighting area LA are different.

For example, the first light-emitting area EA1 and the first lighting area LA1 of the first pixel PX1 included in the pixel group PG_4 may have substantially the same planar shape, and the fourth light-emitting area EA4 and the fourth lighting area LA4 of the fourth pixel PX1 included in the pixel group PG_4, may have substantially the same planar shape. The first lighting area LA1 and the fourth lighting area LA4 may have substantially the same planar shape.

The third light-emitting area EA3 and the third lighting area LA3 of the third pixel PX3 included in the pixel group PG_4 may have substantially the same planar shape, and the sixth light-emitting area EA6 and the sixth lighting area LA6 of the sixth pixel PX6 included in the pixel group PG_4, may have substantially the same planar shape. The third lighting area LA3 and the sixth lighting area LA6 may have substantially the same planar shape.

In addition, the second light-emitting area EA2 and the second lighting area LA2 of the second pixel PX2 included in the pixel group PG_4, and the fifth light-emitting area EA5 and the fifth lighting area LA5 of the fifth pixel PX5 included in the pixel group PG_4, are substantially the same as those in the one or more embodiments corresponding to FIG. 10, so the description thereof is omitted.

In the one or more embodiments corresponding to FIG. 13, it is shown that among the plurality of pixels PX included in the pixel group PG_4, each of the first pixel PX1, the third pixel PX3, the fourth pixel PX4, and the sixth pixel PX6 has substantially the same planar shape of the light-emitting area EA and the lighting area LA that overlap, and each of the second pixel PX2 and the fifth pixel PX5 has different planar shapes of the light-emitting area EA and the lighting area LA that overlap, but the present disclosure is not limited thereto, and may be changed variously.

For example, among the plurality of pixels PX included in the pixel group PG_4, the second pixel PX2, the third pixel PX3, the fifth pixel PX5, and the sixth pixel PX6 may each have substantially the same planar shape of the light-emitting area EA and the lighting area LA that overlap, and the first pixel PX1 and the fourth pixel PX4 may have different planar shapes of the light-emitting area EA and the lighting area LA that overlap.

As another example, among the plurality of pixels PX included in the pixel group PG_4, each of the first pixel PX1, the second pixel PX2, the fourth pixel PX4, and the fifth pixel PX5 may have substantially the same planar shape of the light-emitting area EA and the lighting area LA that overlap, and each of the third pixel PX3 and the sixth pixel PX6 may have different planar shapes of the light-emitting area EA and the lighting area LA that overlap.

The display device according to the embodiments illustrated in FIG. 10 to FIG. 13 may have substantially the same effect as the display device described above with reference to FIG. 1 to FIG. 9.

A display device according to an embodiment may be applied to various electronic devices. An electronic device according to an embodiment may include the display device, and may further include modules or devices having additional functions other than the display device.

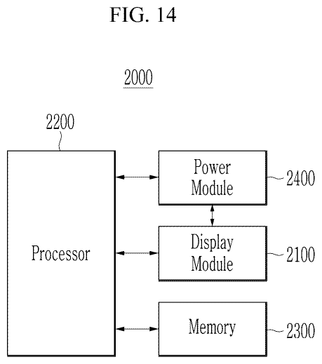

FIG. 14 is a block diagram of an electronic device according to an embodiment. Referring to FIG. 14, the electronic device 2000 according to an embodiment may include a display module 2100, a processor 2200, a memory 2300, and a power module 2400.

The processor 2200 may include at least one of a central processing unit (CPU), an application processor (AP), a graphic processing unit (GPU), a communication processor (CP), an image signal processor (ISP), and a controller.

The memory 2300 may store data information necessary for operations of the processor 2200 or the display module 2100. When the processor 2200 executes an application stored in the memory 2300, video data signals and/or input control signals are transmitted to the display module 2100, and the display module 2100 can process the received signals to output video information through the display screen.

The power module 2400 may include a power supply module such as a power adapter or battery device, and a power conversion module that converts the power supplied by the power supply module to generate the power necessary for the operation of the electronic device 2000.

At least one of components of the electronic device 2000 may be included within the display device according to the above-described embodiments. Additionally, some of the individual modules that are functionally included within a single module may be incorporated into the display device, while others may be provided separately from the display device. For example, the display device may include the display module 2100, while the processor 2200, memory 2300, and power module 2400 may be provided in a form of other devices within the electronic device 2000 that are not part of the display device.

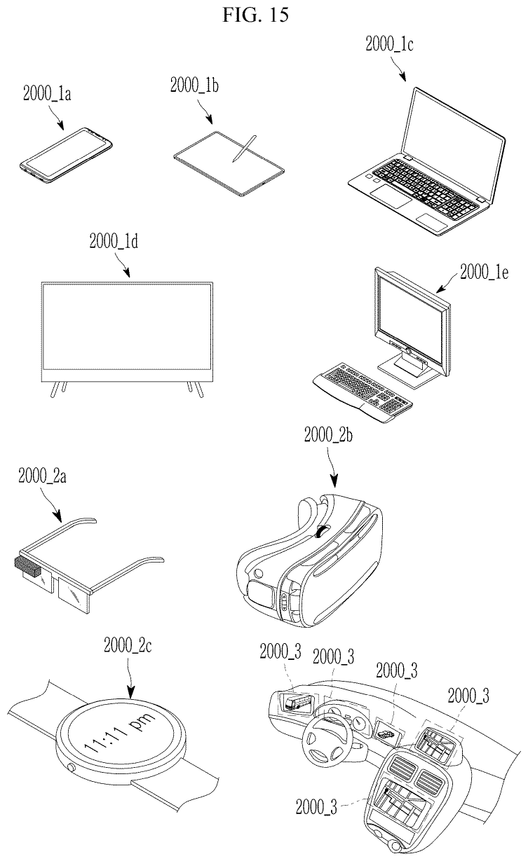

FIG. 15 shows schematic diagrams of electronic devices according to various embodiments.

Referring to FIG. 15, various electronic devices with the display device according to the embodiments may include not only image display electronic devices such as smartphones 2000_1a, tablet PCs 2000_1b, laptops 2000_1c, TVs 2000_1d, desktop monitors 2000_1e, but also wearable electronic devices with display modules such as smart glasses 2000_2a, head-mounted displays 2000_2b, smart watches 2000_2c, as well as automotive electronic devices with display modules 2000_3 such as those placed on car dashboards, center fascias, CID (Center Information Display), room mirror displays, and so on.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims, with functional equivalents thereof to be included therein.

Description of Some of the Reference Characters

| | |
|---|---|
| SUB1: first substrate | SUB2: second substrate |
| DC: display unit | CC: color converter |
| EA: light-emitting area | NEA: non-light-emitting area |
| LA: light-emitting area | NLA: non-light-emitting area |
| ED: light-emitting element | BK: partition wall |
| PX: pixel | PG: pixel group |
| CFL: color filter layer | CCL: color conversion layer |
| QD: quantum dot | SC: scatterer |
| TL: transmitting layer | OP: contact opening |
| PDL: pixel definition layer | |

What is claimed is:

1. A display device comprising:
a first substrate comprising light-emitting areas, and a non-light-emitting area surrounding the light-emitting area in plan view,
transistors above the first substrate,
light-emitting elements connected to the transistors,
a common voltage wiring above the first substrate, and connected to the light-emitting elements through a contact opening in the non-light-emitting area, and
a pixel definition layer that defines the light-emitting areas and the contact opening of a pixel group, the pixel group comprising:
a fifth light-emitting area and a second light-emitting area apart in a first direction with the contact opening therebetween,
a sixth light-emitting area and a fourth light-emitting area apart from the fifth light-emitting area in a second direction crossing the first direction, and
a third light-emitting area and a first light-emitting area apart from the second light-emitting area in the second direction.

2. The display device of claim 1, wherein the fifth light-emitting area and the second light-emitting area have a symmetrical shape centered on the contact opening.

3. The display device of claim 2, wherein the sixth light-emitting area and the third light-emitting area have substantially a same planar shape,
wherein the fourth light-emitting area and the first light-emitting area have substantially a same planar shape,
wherein the area of the fifth light-emitting area and the area of the second light-emitting area are substantially equal,
wherein the area of the fifth light-emitting area is larger than the area of the sixth light-emitting area and the area of the fourth light-emitting area, and
wherein the area of the second light-emitting area is larger than the area of the third light-emitting area and the area of the first light-emitting area.

4. The display device of claim 1, wherein the second light-emitting area, the contact opening, and the fifth light-emitting area are arranged sequentially along the first direction, and
wherein the third light-emitting area, the first light-emitting area, the sixth light-emitting area, and the fourth light-emitting area, are arranged sequentially along the first direction.

5. The display device of claim 4, wherein the contact opening is surrounded by the fifth light-emitting area, the second light-emitting area, the first light-emitting area, and the sixth light-emitting area.

6. The display device of claim 1, wherein respective corners of the fifth light-emitting area and the second light-emitting area facing the contact opening are chamfered along a side of the contact opening.

7. The display device of claim 1, wherein the pixel group comprises a first pixel group, a second pixel group, and a third pixel group,
wherein the first pixel group and the second pixel group are arranged along the first direction,
wherein the first pixel group and the third pixel group are arranged along a third direction crossing the first direction and the second direction, and
wherein the second pixel group and the third pixel group are arranged along a fourth direction crossing the third direction.

8. The display device of claim 7, wherein the first pixel group, the second pixel group, and the third pixel group comprise the contact opening,
wherein the contact opening in the first pixel group and the contact opening in the third pixel group are apart along the third direction, and
wherein the contact opening in the second pixel group and the contact opening in the third pixel group are apart along the fourth direction.

9. The display device of claim 1, wherein the light-emitting elements comprise a first electrode, a light-emitting layer, and a second electrode connected to the common voltage wiring through the contact opening, which are sequentially stacked.

10. The display device of claim 1, further comprising:
an encapsulation layer above the light-emitting elements;
a second substrate overlapping the first substrate, and comprising lighting areas respectively corresponding to the light-emitting areas, and a non-lighting area surrounding the lighting areas in plan view;
a partition wall between the encapsulation layer and the second substrate, and defining partition wall openings that overlap the light-emitting areas;
a color conversion layer and a transmitting layer within the partition wall openings; and
color filters overlapping the lighting areas,
wherein a planar shape of corresponding ones of the lighting areas is different from a planar shape of the light-emitting areas.

11. The display device of claim 10, wherein the corresponding ones of the lighting areas are larger than the light-emitting areas.

12. The display device of claim 10, wherein the color filters comprise:
a first color filter that overlaps the fifth light-emitting area and the second light-emitting area;
a second color filter that overlaps the sixth light-emitting area and the third light-emitting area; and
a third color filter that overlaps the fourth light-emitting area and the first light-emitting area.

13. The display device of claim 12, wherein the first color filter is a green filter,
wherein the second color filter is a red filter, and
wherein the third color filter is a blue filter.

14. A display device comprising:
a first substrate comprising light-emitting areas, and a non-light-emitting area surrounding the light-emitting area in plan view;
transistors above the first substrate;
light-emitting elements connected to the transistors;
an encapsulation layer above the light-emitting element;
a pixel definition layer defining the light-emitting areas and a contact opening of a pixel group;
a second substrate overlapping the first substrate, and comprising lighting areas corresponding to the light-emitting areas and a non-lighting area surrounding the lighting areas;
color filters overlapping the lighting areas;
a color conversion layer and a transmitting layer between the encapsulation layer and the color filters; and
a common voltage wiring above the first substrate, connected to the light-emitting elements through the contact opening in the non-light-emitting area,
wherein the pixel group comprises:
a fifth light-emitting area and a second light-emitting area apart in a first direction with the contact opening in between, and having symmetry with respect to the contact opening,
a sixth light-emitting area and a fourth light-emitting area apart from the fifth light-emitting area in a second direction crossing the first direction, and
a third light-emitting area and a first light-emitting area apart from the second light-emitting area in the second direction, and
wherein at least one of the lighting areas that overlap the first to sixth light-emitting areas has a shape that is different from that of the first to sixth light-emitting areas.

15. The display device of claim 14, wherein the lighting areas comprise:
a fifth lighting area and a second lighting area overlapping the fifth light-emitting area and the second light-emitting area and having substantially a same shape;
a sixth lighting area and a third lighting area overlapping the sixth light-emitting area and the third light-emitting area and having substantially a same shape; and
a fourth lighting area and a first lighting area overlapping the fourth light-emitting area and the first light-emitting area and having substantially a same shape.

16. The display device of claim 15, wherein the first to sixth lighting areas are larger than corresponding ones of the first to sixth light-emitting areas, and
wherein the first to sixth lighting areas have a different shape from the corresponding ones of the first to sixth light-emitting areas.

17. The display device of claim 16, wherein the color filters comprises:
a first color filter overlapping the fifth lighting area and the second lighting area;
a second color filter overlapping the third lighting area and the sixth lighting area; and
a third color filter overlapping the first lighting area and the fourth lighting area, wherein the first color filter, the second color filter, and the third color filter correspond to different respective colors, and
wherein the first to sixth lighting areas have a quadrangular shape.

18. The display device of claim 14, wherein the fifth lighting area and the second lighting area do not overlap the contact opening.

19. An electronic device comprising a display device comprising:
a first substrate comprising light-emitting areas, and a non-light-emitting area surrounding the light-emitting area in plan view,
transistors above the first substrate,
light-emitting elements connected to the transistors,
a common voltage wiring above the first substrate, and connected to the light-emitting elements through a contact opening in the non-light-emitting area, and
a pixel definition layer that defines the light-emitting areas and the contact opening of a pixel group, the pixel group comprising:
a fifth light-emitting area and a second light-emitting area apart in a first direction with the contact opening therebetween,
a sixth light-emitting area and a fourth light-emitting area apart from the fifth light-emitting area in a second direction crossing the first direction, and
a third light-emitting area and a first light-emitting area apart from the second light-emitting area in the second direction.

20. The electronic device of claim 19, wherein the electronic device comprises a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, a head-mounted display (HMD), a virtual reality (VR) device, or an augmented reality (AR) device.
